(19) United States
(12) Patent Application Publication
(10) Pub. No.: US 2026/0240312 A1
(43) Pub. Date: Aug. 20, 2026

(54) Motorized Grooming Device with Rotational Transmission and Wireless Control

(71) Applicant: ReMonte Harris, Phoenix, AZ (US)

(72) Inventor: ReMonte Harris, Phoenix, AZ (US)

(21) Appl. No.: 19/544,777

(22) Filed: Feb. 19, 2026

Related U.S. Application Data
(60) Provisional application No. 63/760,564, filed on Feb. 19, 2025.

(51) Int. Cl. A46B 13/02; A46B 9/02; A46B 15/00; G01R 19/165; H04W 4/80

(52) U.S. Cl. CPC A46B 13/026; A46B 9/023; A46B 15/0006; A46B 15/0038; G01R 19/16571; A46B 2200/104; H04W 4/80

(57) ABSTRACT

A motorized grooming device includes a housing, a motor, a rotational transmission system (for example, comprising gears and belts), a shaft-supported brush assembly configured to rotate, and a control system that adjusts the speed and direction of rotation. The control system monitors load and reverses direction when resistance exceeds a threshold. The device further includes a rechargeable battery and may include a wireless communication module (e.g., Bluetooth) that enables a mobile device to set operating presets and monitor usage. Alternative embodiments include gear-only or planetary transmissions, alternative brush assemblies and torque detection mechanisms, and variations in sealing, power supply and wireless technology. The invention also encompasses a system comprising the device and a mobile computing device configured for wireless communication.

### CROSS-REFERENCE TO RELATED APPLICATIONS

This application claims the benefit of U.S. Provisional Application No. 63/760,564, filed Feb. 19, 2025 and titled “Mechanized Electric Hair Brush (WaveBrusher)”, the disclosure of which is incorporated herein by reference in its entirety under 35 U.S.C. § 119(e).

### FIELD OF THE INVENTION

The present invention relates generally to powered grooming devices. More particularly, the invention pertains to a motorized hair-grooming apparatus having a housing, an electric motor, a multi-stage rotational transmission and a shaft-supported brush assembly configured for rotating motion. The invention further relates to control systems for such devices, including resistance detection and reversal logic, and to optional wireless connectivity for exchanging operational presets and usage data.

### BACKGROUND

Conventional hair brushes and combs require repeated manual strokes to impart wave patterns or achieve detangling, which can be laborious for coarse, curly or long hair. Some powered grooming devices exist, but many rely on direct drive of a single brush axis or on vibration rather than true rotational motion. When such devices encounter resistance from thick or knotted hair they may stall, causing discomfort or damage to the user's hair or to the device. Existing devices also tend to be manually set and lack the ability to remember user presets or report usage information.

Accordingly, there is a need for a motorized grooming device with a robust transmission system capable of providing smooth, torque-controlled rotation; a control system that can detect resistance and automatically reverse direction to prevent tangling; and optional connectivity that permits a user to configure presets and monitor use from a mobile computing device. There is a further need to make the device adaptable to various hair types and future embodiments by describing alternative transmission mechanisms, control arrangements and housing configurations while retaining broad patent scope.

### SUMMARY OF THE INVENTION

In one aspect, the invention provides a motorized grooming device comprising a housing enclosing an electric motor, a rotational transmission system operatively coupled to the motor, a brush assembly supported by one or more shafts and bearings and configured for rotation, a control system for adjusting rotational speed and direction and for detecting resistance, and a rechargeable power source. In response to resistance exceeding a threshold value, the control system reverses the rotational direction to mitigate tangling. In some embodiments, the device further includes a wireless communication module (for example, a Bluetooth module) configured to communicate with a mobile computing device. The mobile computing device may transmit preset operating parameters to the grooming device and receive usage data from the grooming device during an active wireless connection. The invention also encompasses alternative transmission embodiments (e.g., gear-only, belt-only, planetary gear or direct-drive couplings), alternative resistance detection mechanisms, alternative sealing structures, and related systems comprising the device and a mobile computing device.

### BRIEF DESCRIPTION OF THE DRAWINGS

The following drawings illustrate one embodiment of the invention; alternative embodiments may include variations as described in the specification. Like reference numerals refer to like elements throughout the several views.

FIG. 1 is a perspective view of an exemplary motorized grooming device showing the protective case back cover (1), front fixing cover (2), handle (4), speed button (7), power button (8), button panel (12), bristle adhesive strips (13), charging port small cover (17), and handle bottom cover (11).

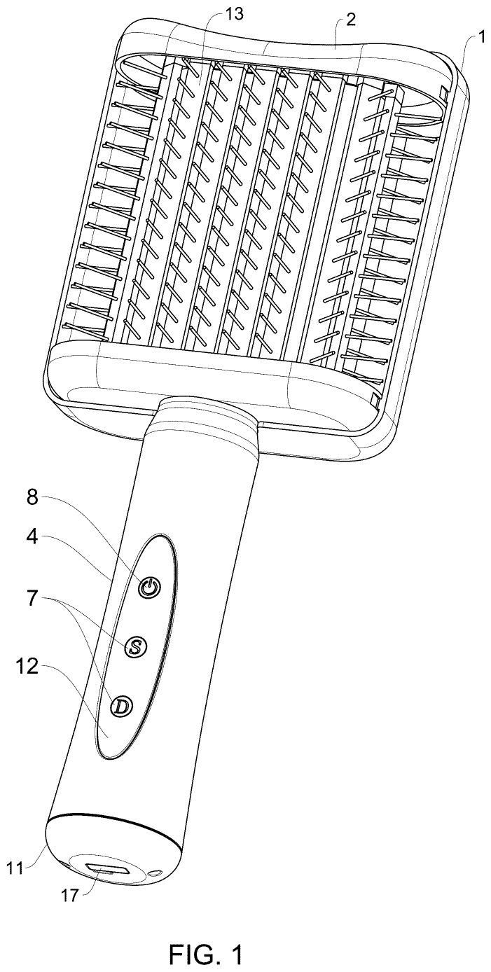

FIG. 2 is a front elevation view of the grooming device showing the front fixing cover (2), protective case back cover (1), bristle adhesive strips (13), handle (4), power button (8), speed button (7), button panel (12), and handle bottom cover (11).

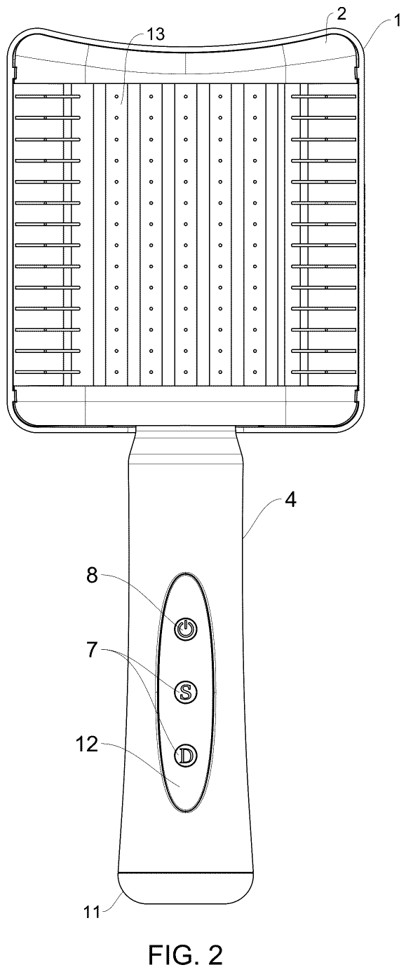

FIG. 3 is a rear elevation view of the grooming device showing the protective case back cover (1), handle (4), battery cover (6), and handle bottom cover (11).

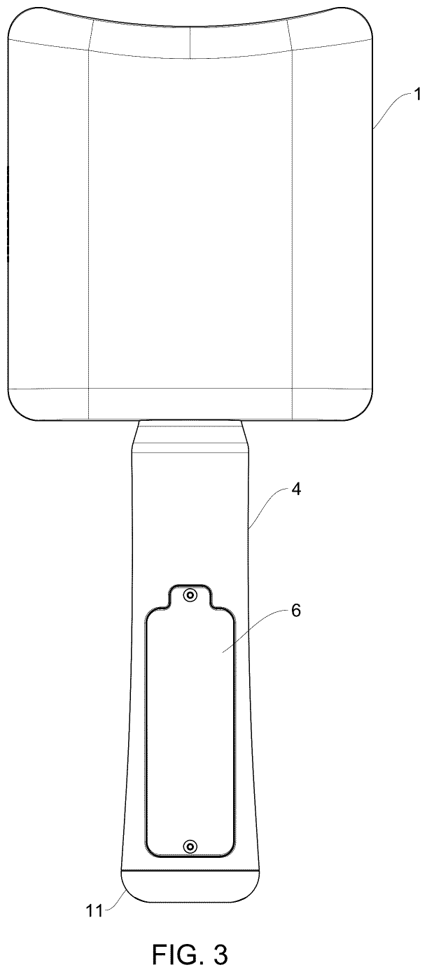

FIG. 4 is a top plan view of the grooming device showing the protective case back cover (1), front fixing cover (2), and bristle adhesive strips (13).

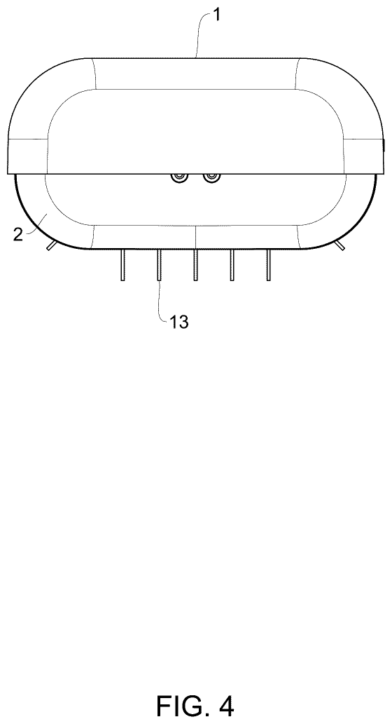

FIG. 5 is a bottom plan view of the grooming device showing the front fixing cover (2), bristle adhesive strips (13), protective case back cover (1), and charging port small cover (17).

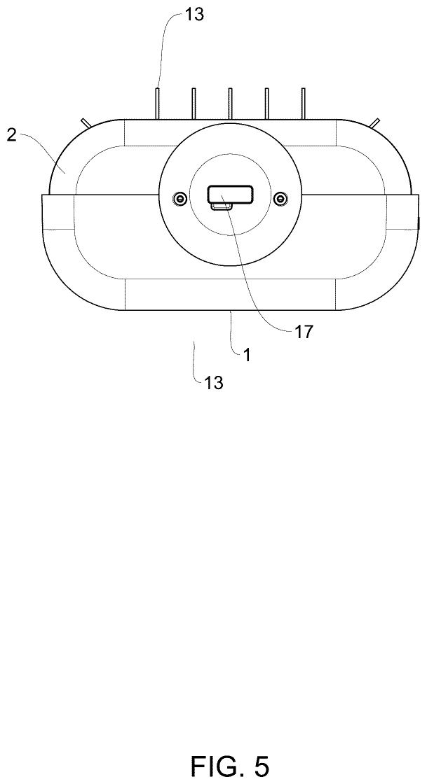

FIG. 6 is a right side elevation view of the grooming device showing the front fixing cover (2), bristle adhesive strips (13), protective case back cover (1), handle (4), battery cover (6), button panel (12), and handle bottom cover (11).

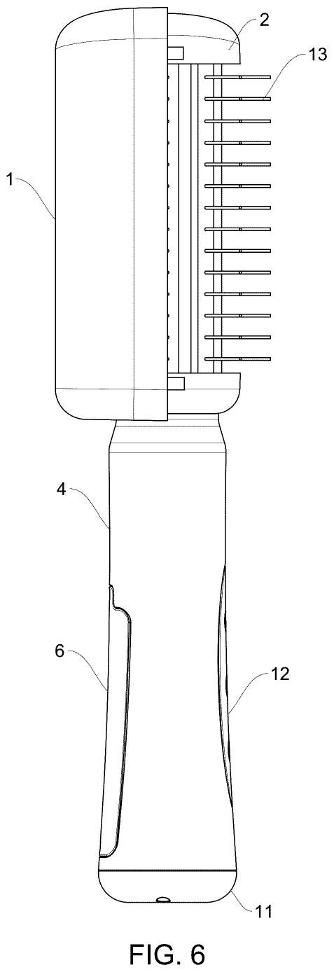

FIG. 7 is a left side elevation view of the grooming device showing the front fixing cover (2), bristle adhesive strips (13), protective case back cover (1), handle (4), battery cover (6), button panel (12), and handle bottom cover (11).

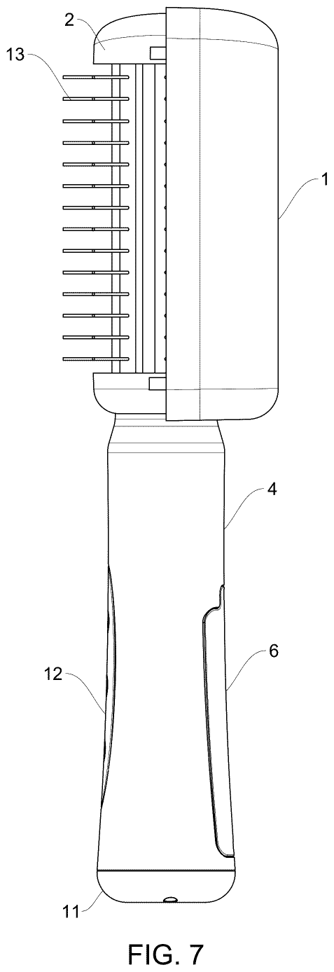

FIG. 8 is an exploded perspective view of the grooming device showing the protective case back cover (1), front fixing cover (2), battery compartment (3), mounting bracket front cover (9), motor cover (10), handle (4), battery cover (6), speed button (7), power button (8), button panel (12), bristle adhesive strips (13), gear (14), motor gear (15), belt pulley (16), charging port small cover (17), belt (18), bearing (21), steel shaft (23), battery (24), drive motor (25), switch PCB (26), power PCB (27), handle bottom cover (11), and waterproof rings (28).

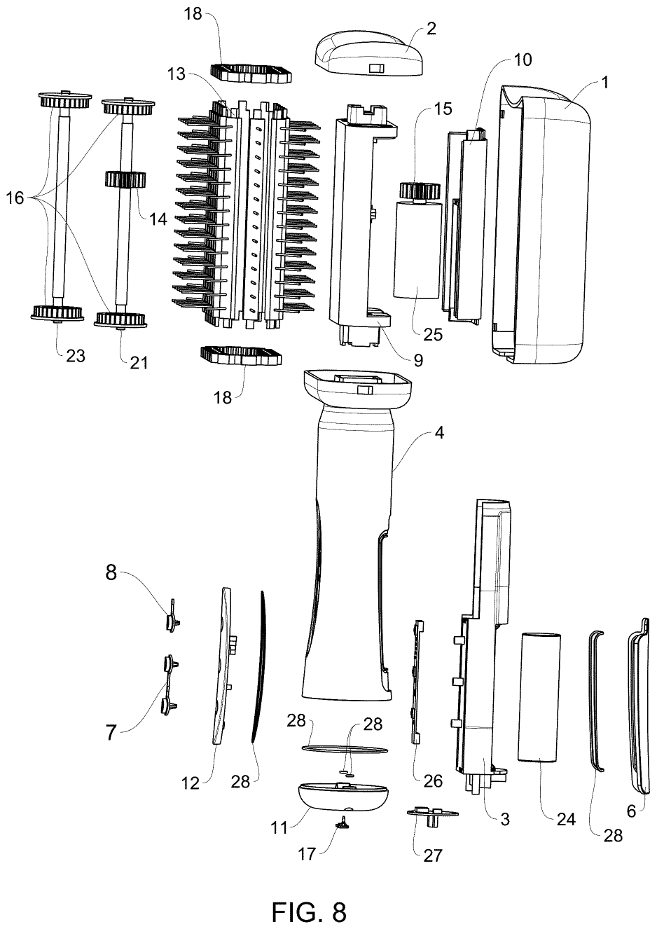

FIG. 9 is a front cross-sectional view of the grooming device, taken along a plane bisecting the front elevation, showing the internal arrangement of the protective case back cover (1), front fixing cover (2), bristle adhesive strips (13), handle (4), power button (8), speed button (7), button panel (12), and handle bottom cover (11).

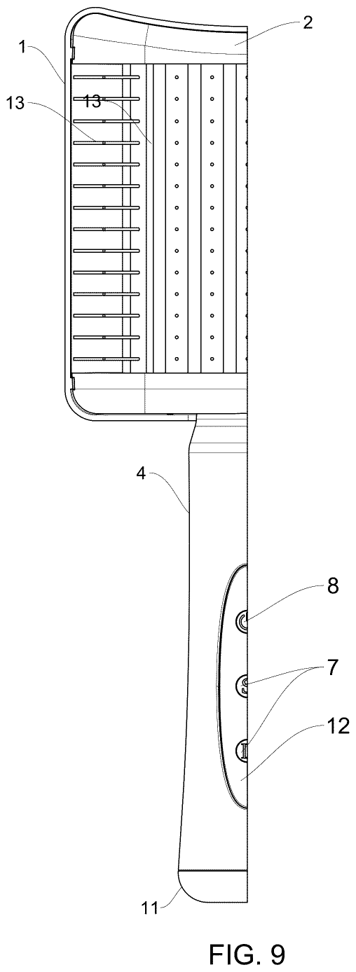

FIG. 10 is a second cross-sectional view of the grooming device showing the internal arrangement of the protective case back cover (1), front fixing cover (2), mounting bracket front cover (9), motor cover (10), bristle adhesive strips (13), motor gear (15), belt pulley (16), belt (18), handle (4), power button (8), speed button (7), battery cover (6), battery (24), drive motor (25), switch PCB (26), power PCB (27), handle bottom cover (11), and charging port small cover (17).

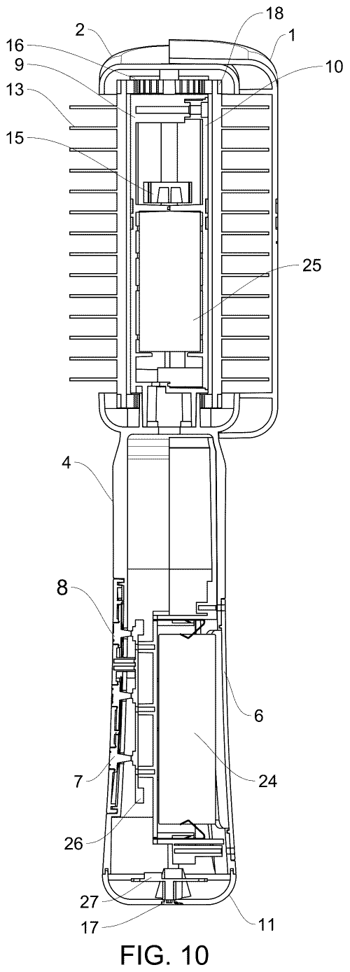

FIG. 11 is a schematic block diagram of the electrical control system of the grooming device, illustrating the functional relationships among the rechargeable battery (24), power management circuit (27), charging interface (17), microcontroller (26), motor driver circuit, drive motor (25), current sensing circuit, user interface including speed button (7), power button (8) and button panel (12), wireless communication module, and an external mobile computing device configured to exchange preset operational parameters and usage data via a wireless connection.

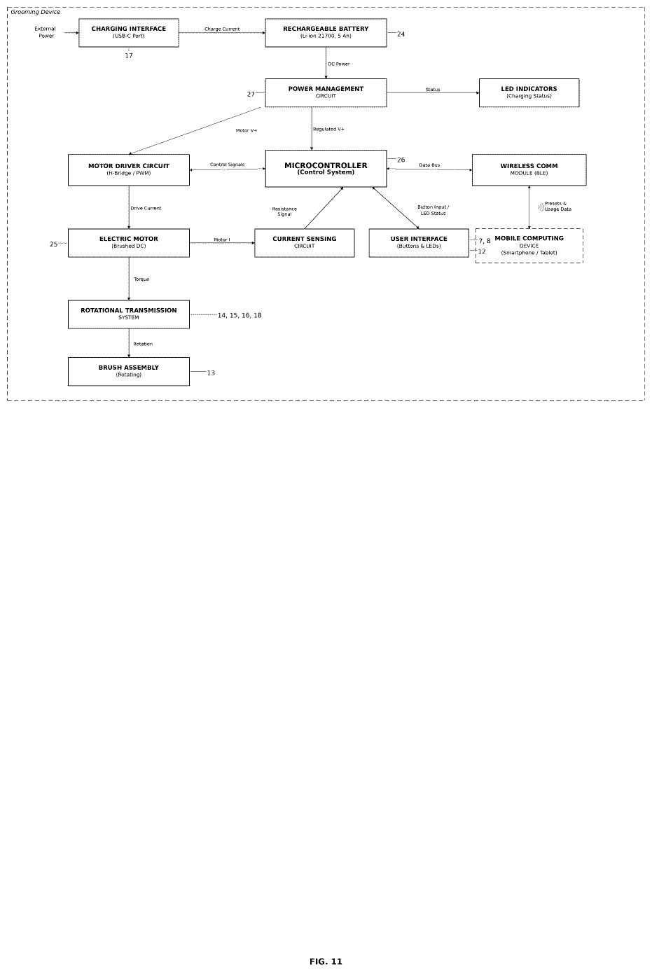

### DETAILED DESCRIPTION OF THE INVENTION

### Overview

The embodiments described herein relate to a motorized grooming device configured to deliver controlled rotational motion to a brush assembly. The device includes multiple subsystems: (i) a mechanical assembly comprising a housing, motor, transmission components and brush assembly; (ii) an electrical subsystem for driving the motor, detecting resistance and controlling operation; (iii) a power subsystem including a rechargeable battery and charging interface; and (iv) an optional wireless communication subsystem for exchanging data with a remote device. While specific embodiments are described with reference to belts, gears, battery types, and control logic, those skilled in the art will recognize that variations may be employed without departing from the scope of the invention.

### Mechanical Assembly

### Housing and Motor

The device includes a housing configured to be handheld by a user. The housing has internal compartments that enclose and support an electric motor, a rotational transmission system and a brush assembly. In one embodiment, the motor is a brushed DC motor rated for use with a rechargeable lithium-ion battery. The motor is mounted within the housing using fasteners or brackets such that its output shaft is operatively coupled to the transmission system.

### Rotational Transmission System

The motor drives a rotational transmission system that transfers torque to the brush assembly. In one embodiment, the transmission system includes a gear reduction stage and a flexible torque transfer member such as a belt. Specifically, a motor gear fixed to the motor's shaft meshes with an intermediate gear or gear train; the intermediate gear is operatively coupled to a belt gear; and a flexible belt or band engages the belt gear and a driven gear attached to the central shaft supporting the brush assembly. Multiple belts may be arranged in parallel to provide balanced torque transmission. The belt may be made of an elastomeric material or other suitable flexible material. The gear teeth may be formed of acetal resin (POM), nylon or other engineering plastics.

In alternative embodiments, the rotational transmission system may comprise a direct gear coupling without a belt (gear-only), a planetary gear assembly, a friction drive system, or a direct motor-to-shaft coupling. These alternative embodiments are contemplated to provide broad coverage and to permit future design modifications. The term “rotational transmission system” as used herein encompasses any torque transfer mechanism operatively coupled between the motor and the brush assembly.

### Brush Assembly

The brush assembly is rotatably supported within the housing. In one embodiment, the brush assembly comprises a rotating brush support structure (e.g., a plate) configured to carry a plurality of bristles, brush strips or grooming elements. The brush support structure is mounted on a central shaft, which is supported by one or more bearings positioned within the housing to provide stable rotational motion. The bearings may be ball bearings or sleeve bearings formed from metal or polymer. The brush support structure is fixed to the driven gear or shaft such that rotation of the shaft causes rotation of the brush support structure.

The brush support structure may be generally planar; however, other shapes (e.g., cylindrical, conical, domed) are contemplated. The brush assembly may be removably secured to the housing by one or more covers or retainers to permit replacement or cleaning. In certain embodiments, different brush support structures may be interchangeable to suit various hair textures or grooming applications (for example, coarser bristles for thick hair, softer bristles for delicate hair, or pet-specific grooming heads).

### Support Structure and Sealing

The housing includes an upper cover and a lower body that can be sealed together to form a waterproof or splash-resistant enclosure. A gasket or O-ring may be positioned between mating surfaces to inhibit ingress of moisture. In other embodiments, an overmolded elastomeric seal or a compression seal may be used. The housing may include transparent panels to allow observation of the transmission system and illumination elements; such panels may be sealed using adhesives or gaskets. The brush assembly is accessible via a face cover that may be removed to service or replace the brush support structure.

### Electrical and Control Subsystems

### Motor Driver and Speed Control

The electric motor is connected to a motor driver circuit that receives control signals from a microcontroller or other control circuitry. The motor driver regulates the motor voltage and current to provide multiple selectable speed levels. In one embodiment, the device provides four discrete speed settings, ranging from approximately 150 rpm to 300 rpm. The control circuitry may employ pulse-width modulation (PWM) to adjust motor speed.

The control interface includes a power button and one or more adjustment buttons accessible on an exterior portion of the housing. The power button toggles the device on and off and may also cycle rotation direction between clockwise and counterclockwise. The adjustment buttons increase or decrease the selected speed level. One or more visual indicators (e.g., LED indicators) are provided to display operational status, including speed level and battery state. For example, a green LED may illuminate when the battery is above a predetermined threshold, flash during charging, or indicate completion of charging.

### Resistance Detection and Direction Reversal

To prevent hair tangling or device stalling, the control system includes resistance detection logic configured to monitor the load on the motor. In one embodiment, the motor current is monitored by the microcontroller via a current sensing circuit. When motor current exceeds a threshold corresponding to a resistance value (for example, a torque equivalent of 1.3 N on the brush assembly), the control system interprets this as a blockage. In response, the control system reverses the rotational direction of the brush assembly. The device may also include a time delay or hysteresis to prevent rapid oscillations. After reversal and clearance of the blockage, normal rotation resumes. Alternative embodiments may use mechanical clutches, strain gauges or torque sensors to detect resistance, and may employ mechanical slip couplings to limit torque. These embodiments are considered equivalent for purposes of the claims.

### Wireless Communication Module

In certain embodiments, the device includes a wireless communication module positioned within the housing and electrically connected to the control system. The module may be a Bluetooth Low Energy (BLE) transceiver configured to communicate with a mobile computing device such as a smartphone or tablet. During an active wireless connection, the mobile computing device may transmit preset operational parameters (e.g., desired speed and direction sequences) to the grooming device and may receive usage data (e.g., operational duration, battery status) from the grooming device. The wireless communication module may also receive firmware updates over the air. Alternative wireless technologies (for example, Wi-Fi) are contemplated, and the term “wireless communication module” is intended to encompass any radio transceiver suitable for exchanging data with a remote device.

The mobile computing device may run an application configured to display the device's status, permit selection of presets, monitor usage patterns and send firmware updates. In one embodiment, presets are stored on the mobile computing device and transmitted to the grooming device at the start of a session; no persistent storage of usage data occurs in the grooming device when no connection is active. However, in other embodiments the grooming device may include local memory for storing usage history or preset information.

### Power Subsystem

The device includes a rechargeable power source positioned within the housing. In a preferred embodiment, the power source comprises a cylindrical 21700 lithium-ion cell having a capacity of approximately 5 Ah. Alternative battery formats, including 18650 cells, prismatic packs, or multiple cells in series or parallel, may be used. The battery is connected to a power management circuit that controls charging and discharge, protects against over-current and over-temperature events, and provides voltage regulation to the motor driver and control circuitry.

The device includes a charging interface accessible from an exterior portion of the housing. In one embodiment, the charging interface is a USB-C port sealed with a protective flap or gasket. A charging indicator LED may illuminate red during charging and green when charging is complete. Alternative charging interfaces, such as magnetic connectors or inductive wireless charging coils, may be employed. The battery compartment may be accessible for replacement or service.

### Alternative Embodiments and Variations

To provide broad coverage, the invention contemplates various alternative embodiments and combinations. As noted, the rotational transmission system may be belt-driven, gear-only, planetary gear or direct drive. The brush assembly may be planar, cylindrical, conical, domed or other shapes, and may be removably coupled using latches, screws, snap-fits or magnetic couplings. The resistance detection mechanism may rely on electronic current sensing, mechanical clutches, torque sensors, slip couplings or combinations thereof. The control system may provide discrete speed levels or continuously variable speeds, may permit user-defined motion profiles, and may include additional sensors (e.g., temperature sensors, gyro sensors) to adapt operation. The wireless communication module may support Bluetooth, Wi-Fi, near-field communication (NFC) or other protocols, and may exchange additional data such as firmware updates, preset libraries or user metrics. The power source may comprise one or more rechargeable cells, may be user-replaceable, and may be charged via wired or wireless charging interfaces. The housing may be sealed by gaskets, overmolded elastomer, adhesives or compression seals, and may include transparent panels or decorative features.

Those skilled in the art will appreciate that the foregoing description of preferred and alternative embodiments provides examples rather than exhaustive details, and that numerous modifications and variations are possible without departing from the scope of the invention as defined in the claims.

What is claimed is:

1. A motorized grooming device, comprising:
a housing;
a motor positioned within the housing;
a rotational transmission system operatively coupled to the motor, the transmission system comprising at least one gear and at least one flexible torque transfer member configured to transfer rotational force from the motor;
a shaft-supported brush assembly driven by the transmission system and configured to rotate about a longitudinal axis;
a control system configured to selectively adjust rotational speed and direction of the brush assembly;
a resistance detection mechanism configured to detect a resistance condition when a predefined threshold is exceeded and to cause the control system to reverse rotational direction in response to the resistance condition; and
a rechargeable battery coupled to supply power to the motor and the control system.

2. The device of claim 1, wherein the flexible torque transfer member comprises at least one belt positioned between a driving gear and a driven gear.

3. The device of claim 1, wherein the rotational transmission system comprises a gear-only transmission stage without a flexible torque transfer member.

4. The device of claim 1, wherein the brush assembly comprises a brush support structure carrying a plurality of bristles or grooming elements and mounted on a shaft supported by at least one bearing within the housing.

5. The device of claim 1, wherein the control system comprises a motor driver circuit configured to provide a plurality of discrete speed settings, and a user interface comprising a power button and at least one speed adjustment button.

6. The device of claim 1, wherein the resistance detection mechanism comprises a current sensing circuit configured to monitor motor current and to signal reversal of rotation when the current exceeds a predefined threshold.

7. The device of claim 1, further comprising a wireless communication module positioned within the housing and configured to communicate with a mobile computing device.

8. The device of claim 7, wherein the wireless communication module comprises a Bluetooth module.

9. The device of claim 7, wherein the mobile computing device is configured to transmit preset operational parameters to the grooming device and to receive usage data from the grooming device during an active wireless connection.

10. The device of claim 1, wherein the rechargeable battery comprises a lithium-ion cell housed within the housing and electrically connected to a charging interface positioned on the housing.

11. A system, comprising:
a motorized grooming device according to claim 1; and
a mobile computing device in wireless communication with the grooming device via the wireless communication module,
wherein the mobile computing device is configured to transmit preset operational parameters to the grooming device and to receive usage data from the grooming device during an active wireless connection.
